(19) United States
(12) Patent Application Publication
(10) Pub. No.: US 2006/0213444 A1
(43) Pub. Date: Sep. 28, 2006

(54) Deposition apparatus and deposition method

(75) Inventors: Seiji Samukawa, Sendai-shi (JP); Toshihisa Nozawa, Amagasaki-City (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignees: TOKYO ELECTRON LIMITED, Minato-ku (JP); SEIJI SAMUKAWA, Sendai-shi (JP)

(21) Appl. No.: 11/377,291

(22) Filed: Mar. 17, 2006

Related U.S. Application Data
(63) Continuation-in-part of application No. PCT/JP04/13357, filed on Sep. 14, 2004.

(30) Foreign Application Priority Data
Sep. 17, 2003 (JP) 2003-325004

(51) Int. Cl. C23C 16/00; H05H 1/24; B05C 11/00

(52) U.S. Cl. 118/723 ME; 118/715; 118/723 R; 427/248.1; 427/569; 118/697

(57) ABSTRACT

A deposition apparatus (10) comprises a plasma generation chamber (14) to which a pressure is applied with a treatment gas to generate plasma, a deposition chamber (20) in which a substrate is placed and a film is formed on the substrate, and a distribution plate (17) having a plurality of holes and provided between the plasma generation chamber (14) and the deposition chamber (20). A diameter of the hole in the distribution plate (17) has a size such that a pressure of the plasma generation chamber (14) is 2.0 times or more as high as that of the deposition chamber (20). The deposition apparatus (10) further comprises means for applying a predetermined bias voltage between the plasma generation chamber (14) and the deposition chamber (20).

### CROSS-REFERENCE TO RELATED APPLICATION

This is a continuation of International Application PCT/JP2004/013357, with an international filing date of Sep. 14, 2004.

### TECHNICAL FIELD

The present invention relates to a deposition apparatus and a deposition method and more particularly, it relates to a deposition apparatus and a deposition method in which a film can be formed in a short time.

### BACKGROUND ART

A deposition apparatus and a deposition method using CVD are disclosed in Japanese Unexamined Patent Publication No. 2001-185546 (patent document 1) and in Japanese National Publication of International Application No. 2002-539326 (patent document 2).

The patent document 1 discloses a deposition apparatus having a reaction chamber in which a substrate is set and a plasma generation chamber which is separated by electrodes from the reaction chamber in a vacuum container to be evacuated to a vacuum and a film is formed in the reaction chamber. A structure of the electrode part is in the shape of a mesh or a comb. Thus, plasma formed in the plasma generation chamber is confined and a radical can be transmitted. By carrying the radical formed in the plasma generation chamber into the reaction chamber and introducing a second gas into the reaction chamber, a vapor phase reaction with the radical or a surface reaction on the substrate proceeds and the film is formed on the substrate.

The patent document 2 discloses a method of depositing metal on a substrate surface in a deposition chamber. The method comprising (a) a step of depositing a monolayer of metal on the substrate surface by applying a metal molecular precursor gas or vapor including metal onto the substrate surface, so that the surface is saturated by a first reactive species with which the precursor will react by depositing the metal and forming a reaction product, leaving a metal surface covered with ligands from the metal precursor whereby further reaction with the precursor will not occur, (b) a step of terminating flow of the precursor gas or vapor; (c) a step of purging the precursor with an inert gas; (d) a step of providing a first reactive species by supplying at least one radical species having high reactive characteristics with the surface ligands on the metal precursor layer to the substrate surface in the chamber and removing the ligands as the reaction product and saturating the surface; (e) a step of repeating the above steps in order until a metal film having a desired thickness is provided.

The conventional deposition apparatus and the deposition method using CVD are as described above. According to the patent document 1, there is a problem as described below. More specifically, since the reaction chamber for setting the substrate and the plasma generation chamber are separated by the electrode only, the deposition gas flows into the plasma generation chamber and the deposition gas reacts with the radical, so that the film is formed in the plasma generation chamber also.

According to the patent document 2, the monolayer of the metal is formed by applying the metal molecular precursor gas or the vapor containing metal on the substrate surface and after the surface is saturated with the first reactive species with which the precursor reacts by depositing the metal and forming the reactive product, the flow of the precursor gas or the vapor is terminated, and the precursor is purged with the inert gas, and the ligands are removed by suplying the radical species to the substrate surface. Thus, since the purging process is indispensable in the deposition process, it takes time to form the film.

### DISCLOSURE OF THE INVENTION

The present invention was made in view of the above problems and an object of the present invention is to provide a deposition apparatus and a deposition method in which a film is not attached in a plasma generation chamber and a film can be formed in a short time.

A deposition apparatus according to the present invention comprises a plasma generation chamber to which a predetermined treatment gas is introduced to generate plasma at a predetermined pressure, a deposition chamber in which a substrate is placed, and a desired film is formed on the substrate at a predetermined pressure, evacuating means connected to the deposition chamber, for evacuating the deposition chamber, and a distribution plate provided between the plasma generation chamber and the deposition chamber and having a plurality of holes constituted such that a pressure of the plasma generation chamber becomes a positive pressure as compared with a pressure of the deposition chamber.

Thus, the plasma generation chamber and the deposition chamber are separated by the distribution plate and the plurality of holes are formed in the distribution plate so that the pressure of the plasma generation chamber may become the positive pressure as compared with the pressure of the deposition chamber. Therefore, the deposition gas will not flow into the plasma generation chamber. As a result, the film is not formed in the plasma generation chamber. In addition, since a radical can be continuously supplied to the deposition chamber, the substrate is not saturated with the deposition gas as in the conventional case. Since the purging process which is performed in the conventional method is not needed, the deposition time can be reduced.

Preferably, the deposition apparatus comprises means for applying a predetermined bias voltage between the plasma generation chamber and the deposition chamber.

Since the predetermined bias voltage is applied between the plasma generation chamber and the deposition chamber, ions generated in the plasma generation chamber based on the treatment gas are selectively introduced into the deposition chamber according to a polarity of the bias voltage.

More preferably, a diameter of the hole is so constituted that a pressure difference between the plasma generation chamber and the deposition chamber becomes 1.5 times or more.

Still more preferably, the diameter of the hole is so constituted that a pressure difference between the plasma generation chamber and the deposition chamber becomes 2.0 times or more. When the pressure difference becomes 2.0 times or more, the gas passes through the hoe at sonic speed.

As a result, the deposition gas does not flow into the plasma generation chamber.

More preferably, deposition gas supplying means for supplying the deposition gas is provided in the deposition chamber to form the desired film on the substrate, and the deposition gas supplying means has gas spouts which are distributed over almost an entire region of the deposition chamber.

The deposition gas supplying means may be constituted integrally with the distribution plate.

More preferably, the distribution plate has an upper surface on the side of the plasma generation chamber and a lower surface on the side of the deposition chamber, and a diameter of the hole on the upper surface is larger than that on the lower surface.

The distribution plate is preferably formed of carbon, silicon or aluminum.

In addition, plasma is preferably generated using a microwave or a inductive coupled plasma method.

According to another aspect of the present invention, a deposition apparatus comprises a reaction container, means for generating a radical in a plasma generation region in the reaction container, setting means provided in the reaction container for setting a substrate, deposition gas supplying means for supplying a predetermined deposition gas to a deposition region on the substrate set on the setting means, means for confining the deposition gas in the deposition region, and deposition controlling means for controlling a deposition component contained in the deposition gas so that the deposition component is continuously polymerized on the substrate through the radical.

According to another aspect of the present invention, a desired film is deposited on a substrate by confining a deposition gas in a deposition region of the substrate, and a step of continuously polymerizing a deposition component contained in the deposition gas on the substrate through a radical thereby to form a desired film on the substrate.

Since the deposition gas is confined in the deposition region of the substrate and the deposition component in the deposition gas is polymerized on the substrate through the radical, the purging process is not necessary as is needed in the conventional case. As a result, there is provided the deposition method in which the film can be formed in a short time.

According to this deposition method, when a metal film is formed, a hydrogen radical is used, and when an oxide film is formed, an oxygen radical is used, and when a nitride film is formed, a nitrogen radical is used.

Preferably, the step of continuously polymerizing the deposition component through the radical comprises a step of continuously generating the radical and a step of supplying the deposition gas to the deposition region according to the desired film, the step of continuously generating the radical is performed at a first pressure, the step of supplying the deposition gas to the deposition region according to the desired film is performed at a second pressure, and the first pressure is at least 1.5 times as high as the second pressure.

More preferably, the deposition method comprises a step of neutralizing the radical, and the step of continuously polymerizing the radical comprises a step of supplying a neutralized radical to the substrate.

According to another aspect of the present invention, a deposition apparatus comprises a plasma generation chamber to which a pressure is applied with a treatment gas to generate plasma, a deposition chamber in which a substrate is placed and a desired film is formed on the substrate with a deposition gas, a distribution plate provided between the plasma generation chamber and the deposition chamber and having a plurality of holes, in which the hole of the distribution plate has a dimension such that the treatment gas flows from the plasma generation chamber to the deposition chamber.

According to still another aspect of the present invention, a program makes a computer controlling a deposition apparatus execute a deposition method comprising steps of placing a substrate in a deposition chamber, confining a deposition gas in a deposition region of the substrate, and a step of continuously polymerizing a deposition component contained in the deposition gas on the substrate through a radical thereby to form a desired film on the substrate.

In forming a metal film, a hydrogen radical is used, and in forming an oxide film, an oxygen radical is used.

According to still another aspect of the present invention, the program may be stores in a computer readable recording medium.

According to one embodiment of the present invention, the deposition apparatus further comprises a plasma generation means having a planar antenna, wherein the plasma generation means generates the plasma to be generated in the plasma generation chamber.

Preferably, the plurality of slots are formed in the planar antenna.

More preferably, microwave is introduced into the planar antenna.

### BRIEF DESCRIPTION OF DRAWINGS

FIG. 1A is a schematic sectional view showing a deposition apparatus according to one embodiment of the present invention;

FIG. 1B is a plan view of a planar antenna according to one embodiment of the present invention;

FIG. 2A is a view showing a distribution plate;

FIGS. 2B and 2C are cross sectional views showing the distribution plate;

FIG. 3 is a view showing a state in which a gas passes through a hole of the distribution plate;

FIG. 4 is a view showing another example of the hole of the distribution plate;

FIG. 5A is a view showing a step of a conventional deposition method;

FIG. 5B is a view showing a step of the conventional deposition method;

FIG. 5C is a view showing a step of the conventional deposition method;

FIG. 5D is a view showing a step of the conventional deposition method;

FIG. 6A is a view showing a step of a deposition method according to one embodiment of the present invention;

FIG. 6B is a view showing a step of the deposition method according to one embodiment of the present invention; and

FIG. 6C is a view showing a step of the deposition method according to one embodiment of the present invention.

FIG. 7 is a schematic sectional view showing a deposition apparatus according to another embodiment of the present invention.

### BEST MODE FOR CARRYING OUT THE INVENTION

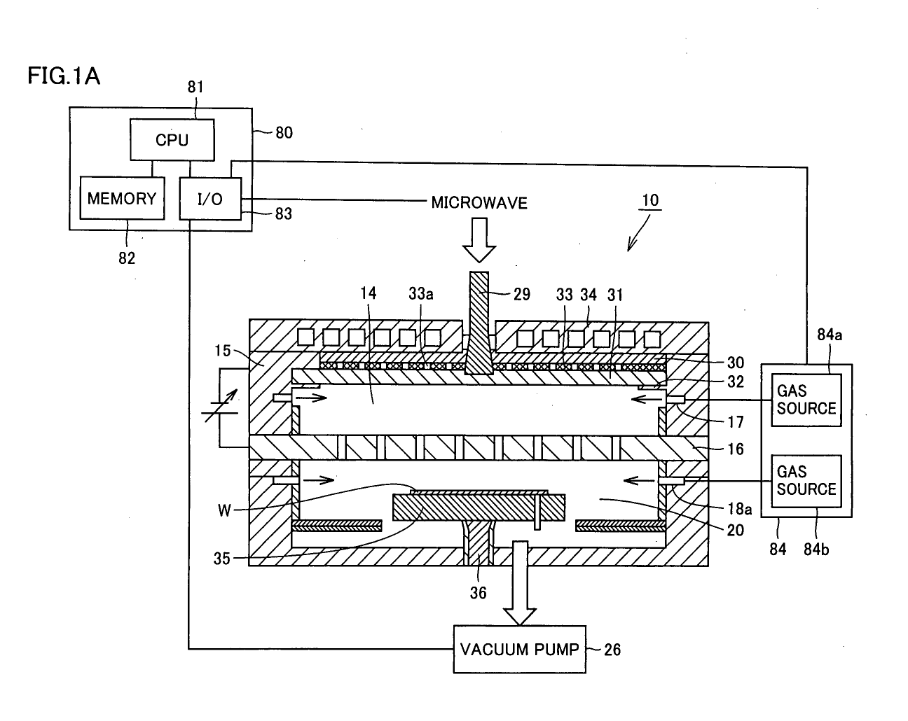

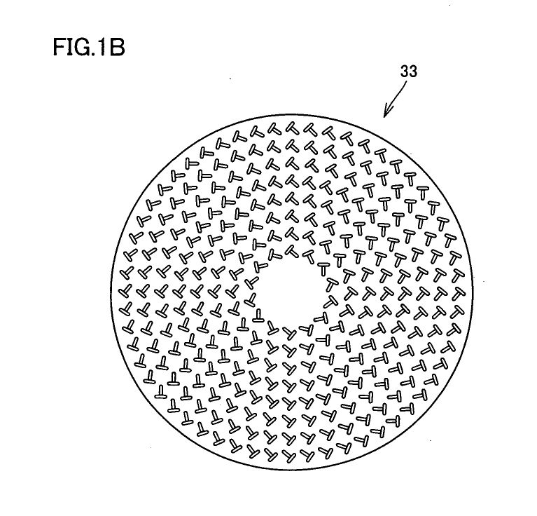

An embodiment of the present invention will be described with reference to the drawings hereinafter. FIG. 1 is a schematic sectional view showing a constitution of a deposition apparatus 10 according to one embodiment of the present invention. Referring to FIG. 1, the deposition apparatus 10 comprises a plasma processing apparatus. The deposition apparatus 10 has a cylindrical treatment container 15 whose side wall and bottom are formed of a conductor such as aluminum.

A plasma generation chamber 14 and a deposition chamber 20 in which a film is formed on a substrate with a deposition gas are provided in the treatment container 15 and they are separated by a distribution plate 16. Many holes having fine diameters are formed in the distribution plate 16. This will be described in detail below.

A ceiling of the treatment container 15 is open and a dielectric plate 31 formed of a ceramic material such as AlN, Al₂O₃, SiO₂ and having a thickness of about 20 mm which penetrates a microwave is provided here through a sealing member such as an O ring in a state it is supported by a support member 32 protruding inside of the treatment container 15.

A slot plate 33 functioning as a disk-shaped or rectangle-shaped planar antenna is provided on the dielectric plate 31. A cooling plate 34 in which a cooling material flows is provided on the slot plate 33 through a dielectric plate 30.

A plurality of concentric slots 33a are formed in a slot plate 33 serving as a planar antenna as shown in FIG. 1A. A space between adjacent slots 33a is set to be λg/4, λg/2 or λg when it is assumed that a wavelength of a microwave passing through the wave guide tube is λg. Thus, the planar antenna serves as a plasma generation means. A slot plate may take different shape. FIG. 1B is a plan view of another shaped slot plate. As shown FIG. 1B, the slot 33a may be T shaped and many other shape may be taken.

The dielectric plate 30 is formed of quart, alumina, aluminum nitride and the like. The dielectric plate 30 is called as a slow wave-plate or a wavelength-shortening plate in some cases, which lowers a propagation speed of a microwave and shortens a wavelength thereof to improve propagation efficiency of the microwave emitted from the slot plate 33.

An upper center of the treatment container 15 is connected to a coaxial waveguide 29. The coaxial waveguide 29 is connected to a microwave generator (not shown) and it propagates the microwave to the slot plate 33. As this waveguide 29, a waveguide having a circular section or rectangular section or the coaxial waveguide can be used.

The deposition chamber 20 houses a pedestal 35 on which an object to be processed such as a semiconductor substrate W is set. The pedestal 35 is made of alumite-treated aluminum into cylindrical or square shape. A support column 36 which is made of aluminum into the column shaped also is provided under this pedestal 35 to support it. The support column 36 is set in the bottom of the treatment container 15 through an insulating material such as ceramic. An electrostatic chuck or a clamp mechanism (not shown) to hold the semiconductor substrate W is provided on an upper surface of the pedestal 35 in some cases.

A cooling jacket (not shown) to circulate cool or warm water is provided on the support column 36 which supports the pedestal 35 to control a temperature of the substrate at the time of the plasma processing. Since a temperature of the pedestal 35 is controlled so as to be lower than that of a wall surface of the treatment container 15, the deposition gas or the like will not adhere on the wall surface of the treatment container 15.

A treatment gas supply part 17 such as a nozzle to introduce a predetermined treatment gas to the plasma generation chamber 14 is provided at a predetermined position of a side surface of the plasma generation chamber 14 in the treatment container 15. The treatment gas supply part 17 may be a plurality of circular gas holes wherein space between gas holes is equal. The treatment gas comprises an inert gas. As the inert gas, argon (Ar) is used and the treatment gas depends on a kind of the film to be formed. For example, H₂+Ar gas, O₂+Ar gas, N₂+Ar gas are used when the film is a metal film, an oxide film, a nitride film, respectively. The treatment gas supply part comprises a quartz pipe, an aluminum structure and the like.

A deposition gas supply part 18 such as a nozzle to introduce the deposition gas to be deposited on the substrate is provided in the side surface of the deposition chamber 20 in the treatment container 15. The deposition gas supply part 18 comprises a quartz pipe, an aluminum structure and the like.

In addition, the deposition gas supply part 18 may be formed in the distribution plate 16.

As the deposition gas, compound gas containing metal such as silicon tetrachloride, tungsten hexafluoride, tantalum pentachloride, trimethyl aluminum, aluminum trichloride, titanium tetrachloride, titanium tetraiodide, molybudenum hexafluoride, zinc dichloride, hafnium tetrachloride, niobium pentachloride, copper chloride and the like are used.

In addition, a gate valve (not shown) to be opened or closed when the substrate is carried in or out of the treatment container 15 is provided in the side wall of the treatment container 15 and a cooling jacket to control a temperature of this side wall is also provided there. In addition, an exhaust outlet connected to a vacuum pump (evacuating means) 26 is provided in the bottom of the treatment container 15, so that the treatment container 15 can be evacuated to a predetermined pressure according to need.

In addition, a variable DC bias voltage or a predetermine bias voltage is applied between the distribution plate 16 and the plasma generation chamber. This bias voltage is set at 10 eV to 50 eV or more according to a treatment condition.

Next, a description is made as to the control unit 80 to control the deposition apparatus 10 so that a desired film is formed on the semiconductor substrate. As shown on the left upper portion of FIG. 1, the control unit 80 comprises a CPU 81, memory 82 for storing a program to execute the above described procedure and I/O (Input and Output) interface 83 to send/receive necessary data to/from sensors and so on (not shown), both of which are connected to the CPU. In FIG. 1, however, only connections from the microwave generator, the vacuum pump 26 and the deposition gas supply part 84 are shown. The deposition gas supply part includes gas sources 84a and 84b for supplying the above described deposition gases. The amount of deposition gas supply is controlled by CPU 81.

The program may be loaded from a computer readable recording medium having the program such as an CD-ROM and a DVD.

The control unit 80 controls transportation and set of the substrate on the pedestal 35, flow of the treatment gas, evacuation of the chamber and so on.

The procedure defined by the program is executed after the substrate is set on the pedestal 35. Upon execution, the program makes the control unit 80 control the deposition apparatus 10 in a manner that the file deposition is made. Alternatively, the deposition method may be controlled by an application specific integrated circuit, embodied hardware of another type, a combination of a hard ware and a software of another type and so on located away from the deposition apparatus 10.

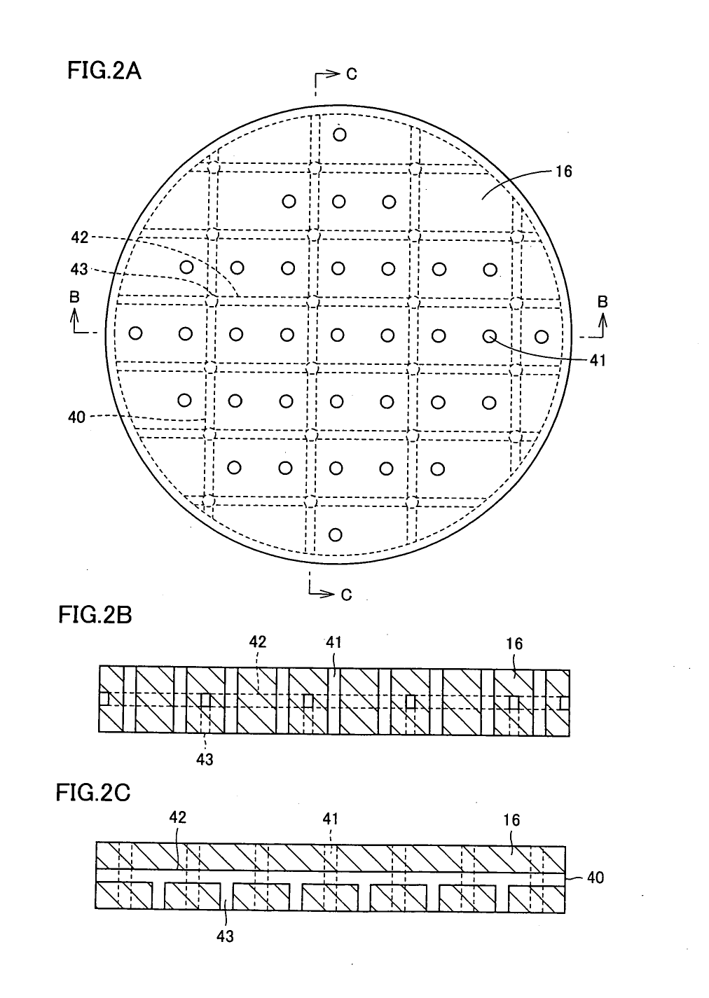

Next, the distribution plate 16 will be described with reference to FIGS. 2A, 2B and 2C. FIG. 2A is a plan view showing the distribution plate 16 wherein a deposition gas supply portion is incorporated, FIG. 2B is a sectional view taken along line B-B in FIG. 2A and FIG. 2C is a sectional view taken along line C-C in FIG. 2A As described above, the holes are formed in the distribution plate 16 provided between the plasma generation chamber 14 and the deposition chamber 20 so that a pressure in the plasma generation chamber 14 becomes positive as compared with the pressure in the deposition chamber 20 by a predetermined pressure difference. That is, a diameter of the hole is selected so that at least 1.5-fold pressure difference may be generated, and preferably 2-fold pressure difference or more may be generated between both chambers. More specifically, although it is preferable that a hole diameter is 1 mm and a hole depth is 5 mm or more, it depends on a treatment gas flow rate.

Referring to FIGS. 2A and 2B, the distribution plate 16 illustrated in this embodiment incorporates deposition gas passages 40 and 42 which supply the deposition gas wherein deposition gas passages 40 and 42 intersect each other. The deposition gas passages 40 and 42 are connected to the deposition gas supply line 18a (refer to FIG. 1) provided at the predetermined position of a periphery of the treatment container 15 and supply the deposition gas to the inside of the deposition chamber 20.

The distribution plate 16 is in the shape of a disk. Many small holes 41; gas passages 40 and 42 aligned like an array around the holes 41 and gas spouts 43 provided at intersections of the gas passages 40 and 42 are formed and deposition gas 20 is introduced. The gas passage 42 and the gas spout 43 are not limited to the illustrated ones and the gas passage 42 may be connected to a wall surface of the hole 41 so that the deposition gas can be discharged to the hole 41.

In order to attain at least 1.5-fold pressure difference between the plasma generation chamber 14 and the deposition chamber 20, both chambers are to be isolated by the distribution plate 16 and the diameter of the hole 41 provided in the distribution plate 16 is to be appropriately selected. When 2-fold pressure difference is implemented between both chambers, the gas passes through the hole 41 at sonic speed. Thus, the deposition gas in the deposition chamber 20 never flows into the plasma generation chamber 14. As a result, the deposition will not occur caused by the deposition gas in the plasma generation chamber 14. The gas flow rate is not necessarily the sonic speed and the same effect can be provided when the gas flow rate is close to it. Therefore, as described above, the pressure of the plasma generation chamber 13 may be 1.5 times as high as that of the deposition chamber 20.

According to a specific example of the pressures of those chambers, the pressure of the plasma generation chamber 14 is 20 mTorr to 500 mTorr and the pressure of the deposition chamber is 10 mTorr to 50 mTorr.

Furthermore, according to distribution of the holes 41 in the distribution plate 16, the holes 41 are to be more densely distributed in the periphery by about 10% than those in the center of the distribution plate 16. For example, while the holes are provided at a pitch of 10 mm in the center, the holes are provided at a pitch of 9 mm in the periphery. This is because a plasma density is high in the center and low in the periphery.

In addition, as a material of the isolating plate 16, although carbon is preferable, aluminum or silicon may be used.

Next, a description will be made of a case a DC or AC bias voltage is applied between the distribution plate 16 and the side surface of the treatment container 15 of the plasma generation chamber 14. When the bias voltage is applied between the distribution plate 16 and the plasma generation chamber 14, a radical and/or an inert gas having a desired polarity of radicals generated in the plasma generation chamber 14 and a charged inert gas can be selectively taken out through the hole or neutralized. For example, positively charged argon Ar⁺ or hydrogen H⁺ radical can be drawn into the deposition chamber 20 or neutralized to cause a desired reaction.

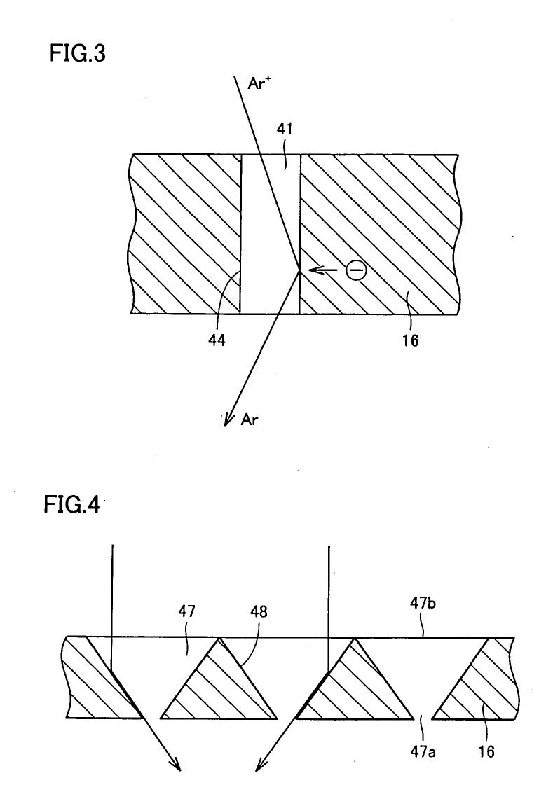

FIG. 3 shows a state in which positively charged argon Ar⁺ gas passes through the distribution plate 16. Here, the deposition gas passage 40 and the gas spout 43 are omitted. Referring to FIG. 3, when the argon Ar⁺ gas passes through the hole, it impinges on a wall surface 44 of the hole 41. At this time, in a case where a negative bias voltage is being applied to the distribution plate 16, the argon Ar⁺ gas is neutralized and it is supplied to the deposition chamber 20 as the neutralized argon Ar gas. Thus, the argon Ar gas can be supplied to the deposition chamber, keeping its kinetic energy. As a result, a processing rate can be increased. In addition, this neutralization is not limited to the inert gas and the same is applied to the radical such as hydrogen, oxygen, nitrogen and the like generated in the plasma generation chamber.

FIG. 4 is a view showing a variation of the embodiment in FIG. 3. Referring to FIG. 4, a diameter of a hole 47 provided in a distribution plate 16 is large on an upper surface and small on a lower surface. Therefore, when an ionized inert gas and the like from the plasma generation chamber 14 passes through the hole 47, it has a high probability of impinging on a wall surface 48, so that more neutralized inert gas or radicals can be provided.

In addition, in order to increase the probability of impinging of the inert gas and the like on the wall surface 48, a thickness of the distribution plate 16 may be increased.

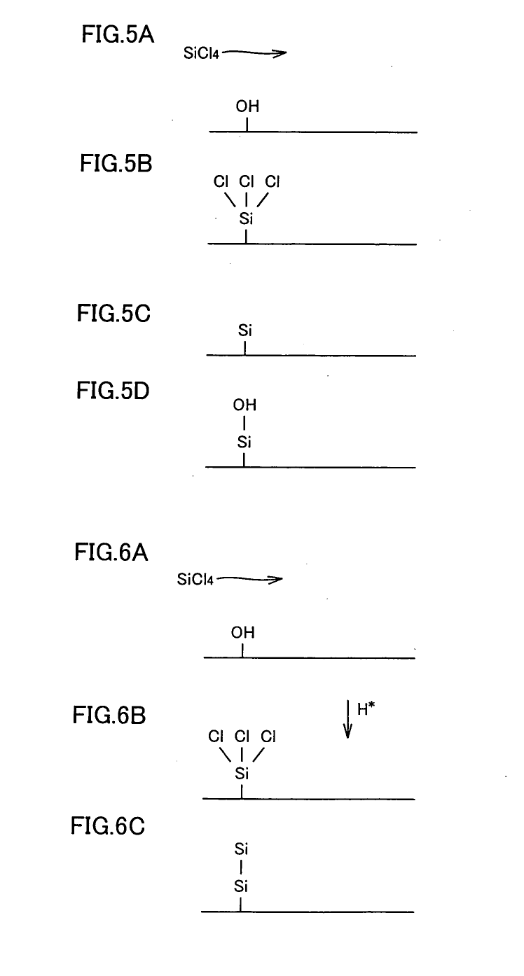

Next, a deposition method according to this embodiment will be described, comparing with the conventional deposition method in the patent document 2. FIGS. 5A to 5D show the conventional deposition method according to the patent document 2 and FIGS. 6A to 6C show the deposition method according to this embodiment step by step

First, the conventional method will be described with reference to FIGS. 5A to 5D. Here, the description will be made of an example in which silicon tetrachloride SiCl₄ is used as the deposition gas. According to the conventional method, silicon tetrachloride SiCl₄ is supplied in a condition a substrate surface is terminated with hydroxyl (—OH) (FIG. 5A).

Then, O—SiCl₃ is adhered to the substrate and HCl is detached. Since the deposition gas is continuously supplied, the substrate surface is gradually covered with Cl atoms (FIG. 5B), and the substrate surface is saturated with the Cl atoms. Thus, in order to remove the superfluous deposition gas, the surface is purged with an inert gas such as Ar or N₂ (FIG. 5C). Then, the original surface saturated with hydroxyl is formed using a hydrogen radical and an oxygen radical (FIG. 5D).

Next, the deposition method according to one embodiment of the present invention will be described. FIGS. 6A to 6C show the deposition method according to one embodiment of the present invention step by step. Referring to FIGS. 6A to 6C, in this embodiment, silicon tetrachloride SiCl₄ is supplied as the deposition gas in a condition that a substrate surface is terminated with hydroxyl (—OH) (FIG. 6A), so that O—SiCl₃ is adhered to the substrate and HCl is detached, which is the same as the conventional method.

However, according to this embodiment, even when the deposition gas is continuously supplied, since H radicals of hydrogen gas are continuously supplied (FIG. 6B) at the same time, Cl atom reacts with the hydrogen radical H, so that the substrate is not covered with Cl and a layer having desired atoms is continuously formed (FIG. 6C).

As described above, according to the deposition method of this embodiment, since the purging process shown in FIG. 5C is not needed, a processing ability for depositing a metal film on the semiconductor substrate can be enhanced.

In addition, since the radical which assists the reaction is continuously supplied, a non-reacted deposition gas can be reduced. Therefore, the non-reacted deposition gas is not contained in the film as is done conventionally. As a result, a high-quality film can be formed.

In addition, the deposition gas is not necessarily supplied continuously to the substrate but it may be supplied intermittently.

In this case, it is preferable to form the film by neutralizing the radical with application of the bias voltage at the time of processing, since the treatment can be performed with higher energy as described above. According to a specific example of the deposition condition, a flow rate of argon gas as the treatment gas is 100 sccm and a flow rate of the deposition gas is 0.1 to 100° sccm.

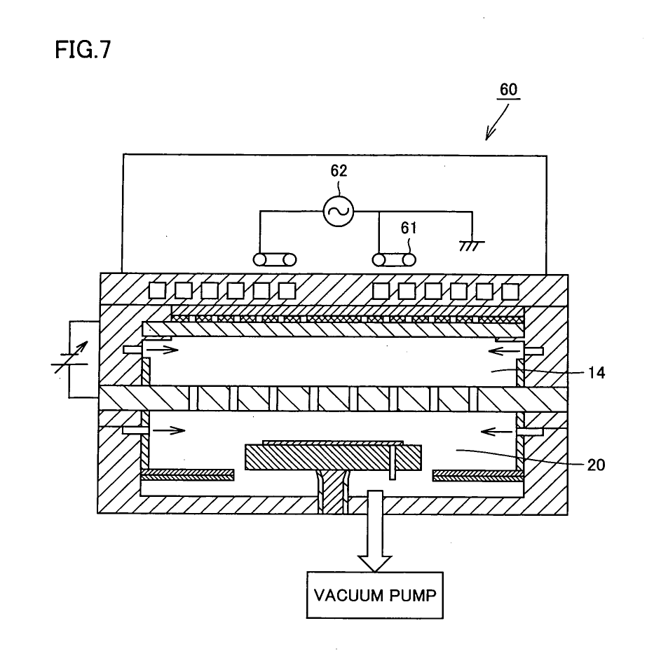

Next, another embodiment of the present invention will be described. FIG. 7 is a schematic sectional view showing a deposition apparatus according to another embodiment of the present invention. Referring to FIG. 7, in this embodiment, the deposition apparatus does not use the microwave to generate plasma like in the above embodiment, but it uses a plasma generation apparatus which generates inductively coupled plasma. That is, this type of plasma deposition apparatus 60 comprises a coil 61 and an AC power supply 62 which applies high frequency to the coil 61, in order to generate plasma in a plasma generation chamber 14. Since other components are the same as those in the above embodiment, their descriptions will not be reiterated.

Although the case where a metal film is formed of silicon on the substrate has been described in the above embodiment, the present invention is not limited to this. Various kinds of oxide films, nitride films and metal films can be formed when the treatment gas and the deposition gas are appropriately selected. That is, when the oxide film, the nitride film, and the metal film are formed, oxygen gas, nitrogen gas, and hydrogen gas are supplied to the plasma generation chamber 14 as the treatment gas, respectively.

In addition, although the case where the hydrogen radical is used as a radical has been described in the above embodiment, the present invention is not limited to this. As described above, another radical such as oxygen or nitrogen may be used depending on the treatment.

Furthermore, although the case where the passage to supply the deposition gas is incorporated in the distribution plate has been described in the above embodiment, the present invention is not limited to this and the distribution plate and the passage to supply the deposition gas may be separately provided.

Although the embodiments of the present invention have been described with reference to the drawings in the above, the present invention is not limited to the above illustrated embodiments. Various kinds of modifications and variations may be added to the illustrated embodiments within the same or equal scope of the present invention.

### INDUSTRIAL APPLICABILITY

According to the deposition apparatus and the deposition method of the present invention, since the film will not be formed in the plasma generation chamber, the substrate is not saturated with the deposition gas as in the conventional case, and the purging process is not needed, the deposition time can be reduced. As a result, this deposition apparatus and deposition method are advantageously used in the deposition treatment.

1. A deposition apparatus comprising:
a plasma generation chamber to which a predetermined treatment gas is introduced to generate plasma at a predetermined pressure;
a deposition chamber in which a substrate is placed, and a desired film is formed on said substrate at a predetermined pressure;
evacuating means connected to said deposition chamber, for evacuating said deposition chamber; and
a distribution plate provided between said plasma generation chamber and said deposition chamber and having a plurality of holes constituted such that a pressure of said plasma generation chamber becomes a positive pressure as compared with a pressure of said deposition chamber.

2. The deposition apparatus according to claim 1, comprising means for applying a predetermined bias voltage between said plasma generation chamber and said deposition chamber.

3. The deposition apparatus according to claim 1, wherein a diameter of said hole is so constituted that a pressure difference between said plasma generation chamber and said deposition chamber becomes 1.5 times or more.

4. The deposition apparatus according to claim 3, wherein a diameter of said hole is so constituted that a pressure difference between said plasma generation chamber and said deposition chamber becomes 2.0 times or more.

5. The deposition apparatus according to claim 1, wherein deposition gas supplying means for supplying said deposition gas is provided in said deposition chamber, and said deposition gas supplying means has gas spouts which are distributed over almost an entire region of said deposition chamber.

6. The deposition apparatus according to claim 5, wherein said deposition gas supplying means is constituted integrally with said distribution plate.

7. The deposition apparatus according to claim 1, wherein said distribution plate has an upper surface on the side of said plasma generation chamber and a lower surface on the side of said deposition chamber, and a diameter of said hole on said upper surface is larger than that on said lower surface.

8. The deposition apparatus according to claim 1, wherein said distribution plate is formed of carbon.

9. The deposition apparatus according to claim 1, wherein said distribution plate is formed of silicon.

10. The deposition apparatus according to claim 1, wherein said distribution plate is formed of aluminum.

11. The deposition apparatus according to claim 1, wherein plasma is generated in said plasma generation chamber using a microwave or an inductive coupled plasma method.

10. A deposition apparatus comprising:
a reaction container;
means for generating a radical in a plasma generation region using a planar antenna provided at the upper portion of said reaction container;
setting means provided in said reaction container, for setting a substrate;
deposition gas supplying means for supplying a predetermined deposition gas to a deposition region on the substrate set on said setting means;
means for confining said deposition gas in said deposition region; and
deposition controlling means for controlling a deposition component contained in said deposition gas so that the deposition component is continuously polymerized on said substrate using said radical.

11. A deposition method for forming a desired film on a substrate comprising:
a step of confining a deposition gas into a deposition region of the substrate; and
a step of continuously polymerizing a deposition component contained in the deposition gas on the substrate using a radical.

12. The deposition method according to claim 11, wherein said desired film is a metal film and said radical is a hydrogen radical.

13. The deposition method according to claim 11, wherein said desired film is an oxide film and said radical is an oxygen radical.

14. The deposition method according to claim 11, wherein said desired film is a nitride film and said radical is a nitrogen radical.

15. The deposition method according to any one of claim 11, wherein
said step of continuously polymerizing the deposition component through the radical comprises a step of continuously generating said radical and a step of supplying the deposition gas to said deposition region according to said desired film,
the step of continuously generating the radical is performed at a first pressure,
the step of supplying the deposition gas to said deposition region according to the desired film is performed at a second pressure, and
said first pressure is at least 1.5 times as high as said second pressure.

16. The deposition method according to any one of claim 11, comprising a step of neutralizing said radical, wherein
said step of continuously polymerizing said radical comprises a step of supplying a neutralized radical to said substrate.

17. A deposition apparatus comprising:
a plasma generation chamber to which a predetermined treatment gas is introduced to generate plasma;
a deposition chamber in which a substrate is placed, and a desired film is formed on said substrate with a deposition gas;
a distribution plate provided between said plasma generation chamber and said deposition chamber and having a plurality of holes, wherein
said hole of the distribution plate has the size such that the size of said plasma generation chamber side is large and the size of said deposition chamber is small and said treatment gas flows from said plasma generation chamber to said deposition chamber only.

18. A program making a computer controlling a deposition apparatus execute a deposition method comprising steps of placing a substrate in a deposition chamber, confining a deposition gas in a deposition region of the substrate, and a step of continuously polymerizing a deposition component contained in the deposition gas on the substrate through a radical thereby to form a desired film on the substrate.

19. The program according to claim 18, wherein said desired film is a metal film and said radical is a hydrogen radical.

20. The program according to claim 18, wherein said desired film is an oxide film and said radical is a nitrogen radical.

21. A computer readable recording medium storing the program according to claims 18.

22. The deposition apparatus according to claim 1, further comprising a plasma generation means having a planar antenna, wherein said plasma generation means generates said plasma to be generated in said plasma generation chamber.

23. The deposition apparatus according to claim 22, wherein a plurality of slots are formed in said planar antenna.

24. The deposition apparatus according to claim 22, wherein microwave is introduced into said planar antenna.
